(19) United States
(12) Patent Application Publication
(10) Pub. No.: US 2006/0038622 A1
(43) Pub. Date: Feb. 23, 2006

(54) Voltage scaling using material-based reference model

(76) Inventors: Vyungchon Choe, San Diego, CA (US); Jagrut Viliskumar Patel, San Diego, CA (US); Rajeev Prabhakaran, San Diego, CA (US)

Correspondence Address: QUALCOMM, INC, 5775 MOREHOUSE DR., SAN DIEGO, CA, 92121, US

(21) Appl. No.: 10/920,825

(22) Filed: Aug. 17, 2004

(51) Int. Cl. H03B 1/00

(52) U.S. Cl. 331/74

(57) ABSTRACT

An electronic circuit including an oscillator and having known physical device characteristics is operated by supplying a core voltage to the electronic circuit from a cold start, measuring output frequency of the oscillator during the cold start, and determining a material index from the output frequency based on the physical device characteristics.

### BACKGROUND OF THE INVENTION

Dynamic voltage and frequency scaling (DVS) is a technique for reducing power consumption on electronic systems such as processors by lowering supply voltage and frequency. DVS enables balancing of performance against energy expenditure. For example, supply voltage can be reduced while a device is operating to reduce power and energy consumption. The balancing takes into consideration that reduction of applied voltage increases device delay and thus is accompanied by a reduction in clock frequency. Accordingly, DVS involves coordinated control of voltage and frequency. For example, static Complementary Metal-Oxide Semiconductor (CMOS) logic commonly used in the design of embedded devices has a voltage-dependent maximum operating frequency.

For a wide variety of real-time embedded systems such as cellular telephones, digital cameras, palm computers, and the like, variable operating frequency resulting from voltage scaling interferes with deadline guarantees, a consideration overlooked by conventional DVS algorithms. In addition, DVS techniques fail to account for voltage droop on capacitors in the integrated circuit, possibly resulting in failure due to performance degradation.

### SUMMARY

In accordance with an embodiment of a voltage scaling system, an electronic circuit including an oscillator and having known physical device characteristics is operated by supplying a core voltage to the electronic circuit from a cold start, measuring output frequency of the oscillator during the cold start, and determining a material index from the output frequency based on the physical device characteristics.

### BRIEF DESCRIPTION OF THE DRAWINGS

Embodiments of the invention relating to both structure and method of operation, may best be understood by referring to the following description and accompanying drawings:

FIG. 1 is a schematic block diagram illustrating an embodiment of an integrated circuit that implements voltage scaling using a material-based reference model;

FIG. 2 is a graph depicting an embodiment of a characterization between device delay and core voltage that is used in a method for operating an electronic circuit or device such as the integrated circuit shown in FIG. 1;

FIG. 3 is a flow chart showing an embodiment of a method for operating an electronic circuit using voltage scaling;

FIG. 4 is a schematic block diagram illustrating an embodiment of an integrated circuit capable of performing voltage scaling using a material-based reference model; and

FIG. 5 is a schematic block diagram depicting an embodiment of a cellular telephone that can implement the illustrative technique for operating a device at an optimal core voltage.

### DETAILED DESCRIPTION

A dynamic voltage scaling technique takes into account physical device characteristics such as one or more of material state, load capacitance, and threshold voltage to dynamically and flexibly set operating parameters to current conditions.

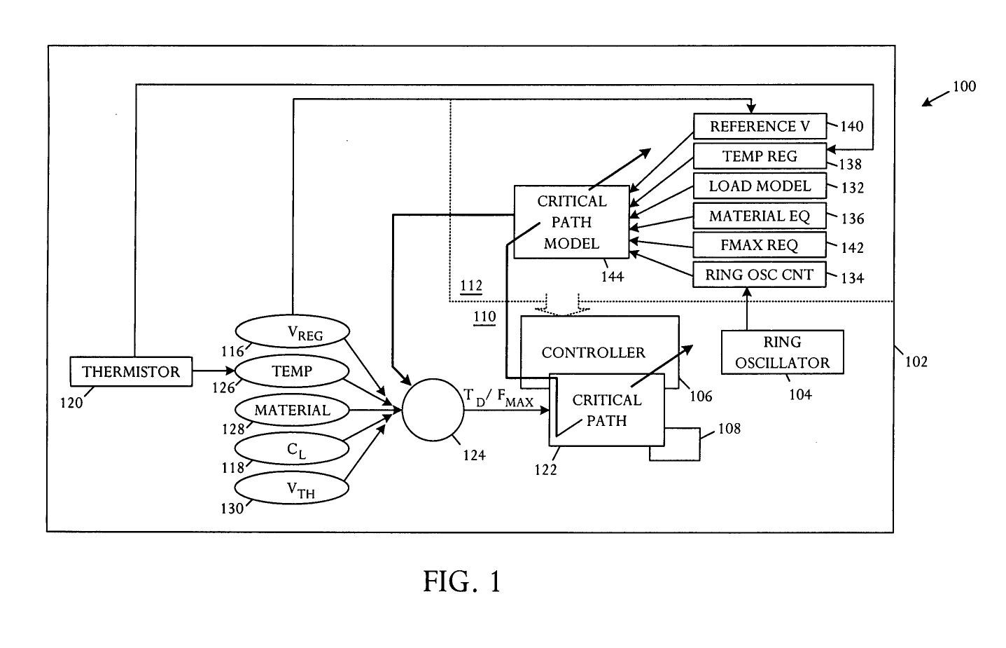

Referring to FIG. 1, a schematic block diagram illustrates an embodiment of an integrated circuit 100 comprising a core 102, an oscillator 104, and a controller 106. The core 102 includes at least one electronic component and/or device 108 and has known physical device characteristics. The oscillator 104 is coupled to the core 102 and generates a timing signal for usage by the core. The controller 106 is coupled to the core 102 and the oscillator 104 and measures oscillator output frequency during a cold start and determines a material index from the output frequency based on the physical device characteristics. Typical physical device characteristics include material, temperature, and voltage characteristics.

The block diagram depicts the integrated circuit 100 including a circuitry or device section 110 and an executable section 112 including code executable on a processor or controller 106. In various embodiments, the executable section 112 can be implemented in software, firmware, programmable logic arrays, state machines, logic, and the like.

The circuitry or device section 110 is shown including various measurement and control devices. A tunable voltage regulator V_{REG} 116 enables control or tuning of integrated circuit voltage. A load capacitor 118 enables control or tuning of integrated circuit load capacitance. The circuitry or device section 110 can include sensors such as a thermistor 120 that can track integrated circuit temperature. The circuitry or device section 110 includes a critical path 122 that is controlled by a control element 124 based on a combination of device delay (Td) and maximum operating frequency. The controller 106 may include part or all of critical path 122. The illustrative control element 124 controls the critical path 122 based on the tunable regulated reference voltage V_{REG} 116, temperature 126, a material value 128, the load capacitance C_{L} 118, and a threshold voltage V_{TH} 130.

The executable section 112 can be considered to include an executable portion and a data storage portion, the data storage portion for holding measured and derived parameters and variables as well as information such as signals, state variables, and the like. In the illustrative example, the storage portion is shown to include registers and/or memory cells containing a load model 132, a ring oscillator count 134, material information 136 such as material constant and/or material index information, temperature information 138, regulated reference voltage information 140, and a maximum frequency parameter 142. The executable section 112 includes a model 144 that models the critical path 122 in the circuitry or device section 110.

The device delay Td or maximum operating frequency Fmax is directly proportional to core voltage, temperature, material type, load capacitance, and threshold voltage. Material type accounts for variations in integrated circuit chip die, for example according to position on a wafer. In one example, the material type can be assigned to various classifications such as slow, nominal, and fast. In other examples, more or fewer classifications can be assigned. Accordingly, the control element 124 accesses the regulated reference voltage V_{REG} 116, temperature 126, the material value 128, the load capacitance C_{L} 118, and the threshold voltage V_{TH} 130 to produce a Td/Fmax control signal for application to the critical path 122.

The critical path model 144 can execute in the controller 106 and use device delay as detected on the ring oscillator 104 or, conversely, ring oscillator frequency, in addition to other known or measurable parameters in the integrated circuit 100 such as core voltage and temperature to identify material type during a cold start. In one implementation, the controller 106 can access operating parameters including oscillator output frequency Fₒᵤₜ, material constant mx, material index X, temperature gradient δT, reference temperature T_{REF}, instantaneous temperature T_{INST}, voltage gradient δV, instantaneous voltage V_{INST}, and reference voltage V_{REF} to determine the value of the material index X according to an equation (1) of the form as follows:
Fₒᵤₜ=mx·X+δT·(T_{REF}−T_{INST})+δV·(V_{INST}−V_{REF}). (1)

The material index and the additional parameters are determined and the maximum frequency Fmax of the critical path is approximated based on the ring oscillator frequency.

For applications that impose a higher execution rate on the integrated circuit 100, the critical path model 144 can recalculate parameters and adjust core voltage and clock tree capacitance so that the critical path 122 does not violate the imposed functional criteria.

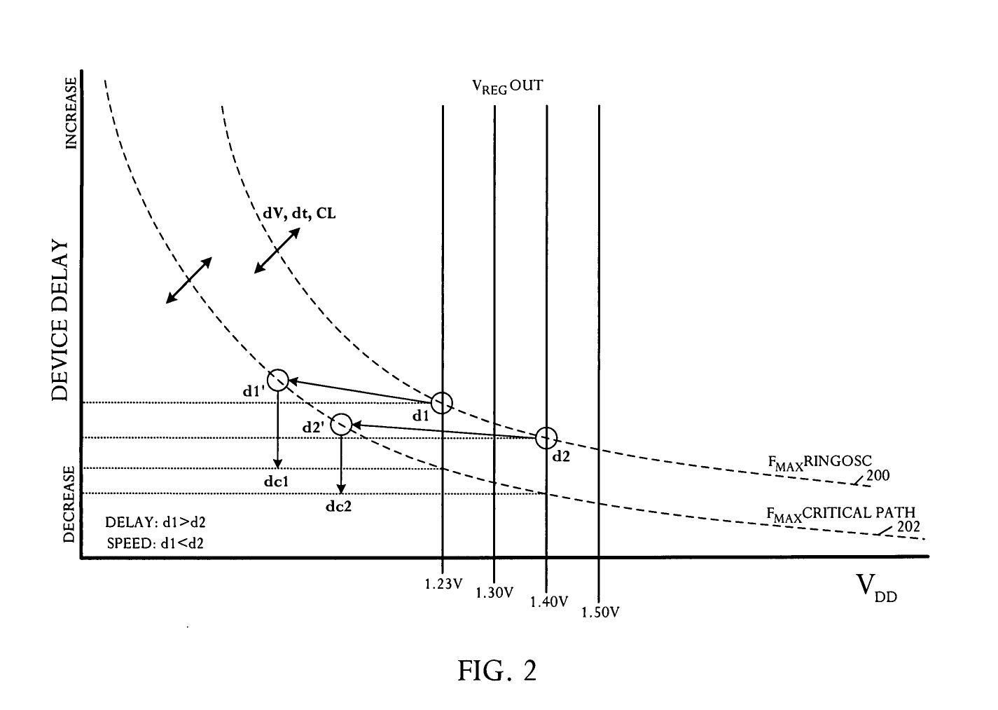

Referring to FIG. 2, a graph depicts an embodiment of a characterization between device delay and core voltage that is used in a method for operating an electronic circuit or device such as the integrated circuit 100 shown in FIG. 1. The integrated circuit 100 includes an oscillator 104 and has known material, temperature, and voltage characteristics. The method can be performed by a controller 106 and comprises supplying a core voltage to the electronic circuit from a cold start, measuring output frequency of the oscillator during the cold start, and determining a material index from the output frequency based on the material, temperature, and voltage characteristics. Operations of the circuit can be controlled by estimating a maximum frequency for a critical path in the electronic circuit based on the material index and frequency of the oscillator.

Correlations depicted in the graph can be expressed using a device delay equations (2, 3, 4) of the form:

$$\begin{matrix}{T}_{d} = \frac{α {C}_{L} {V}_{dd}}{I} & ( 2 ) \\ = \frac{α {C}_{L} {V}_{dd}}{μ {C}_{ox} ( \frac{W}{L} ) {( {V}_{dd} - {V}_{t} )}^{2}} & ( 3 ) \\ = k \frac{α {C}_{L} {V}_{dd}}{{( {V}_{dd} - {V}_{t} )}^{2}} & ( 4 )\end{matrix}$$

where T_{d} is device delay, C_{L} is load capacitance, V_{dd} is core voltage, and I is current. Constant α relates delay as a function of voltage V_{dd}, for example as described in Design of Analog CMOS Integrated Circuits by Behzad Razavi (McGraw-Hill Science/Engineering/Math, 2000). In equation (3), the current is expressed as flow through the integrated circuit device in terms of permeability μ, capacitance through the device oxide layer Cₒₓ, length L and width L of the metal, polysilicon or diffusion layer of the device. The device delay equation leads to the inference that device delay decreases with an increased core voltage, reduced capacitance, and a low temperature.

In an example illustrated by FIG. 2, at a particular voltage, for example 1.4V, the oscillator frequency correlates to point d2, a point that accounts for temperature, threshold voltage V_{TH}, and material index on the oscillator delay curve 200. Load capacitance can be modeled separately depending on the clock tree on which the critical path occurs.

Based on characterization data, point d2′ is identified which is on the critical path delay curve 202 at a core voltage V_{DD} that maintains an appropriate delay in the critical path. The point d2′ correlates the ring oscillator behavior with critical path delay on the device. The model enables the extrapolation of the point d2′ to determine a point dc2 that corresponds to the critical path delay under the existing conditions.

Points d1, d1′, and dc1 illustrate an example of operations at a different V_{REG} OUT level.

The model is also used to generate a minimum voltage that is appropriate to operate the device and a load capacitance within appropriate margins to meet maximum frequency criteria suitable for functional demands on the critical path.

Because the ring oscillator is on the same integrated circuit die as the critical path, the ring oscillator closely tracks changes in critical path parameters such as changes in voltage dV, changes in temperature dT, and load capacitance C_{L}.

Accordingly, the material index and oscillator frequency can be used to approximate the maximum frequency of the critical path. If the delay in the critical path is unsuitable for a particular function or application, core voltage and/or clock tree capacitance can be adjusted to position the critical path delay in an appropriate range.

The illustrative technique correlates oscillator behavior with critical path delay of the electronic circuit and enables a minimum core voltage to be generated and load capacitance to be generated within selected margins to produce a controlled maximum frequency in the critical path.

The method associated with FIG. 2 can be implemented as a reference model, for example in software. A software-based dynamic voltage scaling (DVS) implementation is cost-effective since special DVS hardware can be omitted. DVS techniques implemented solely in hardware are inflexible. Embodiments of a DVS system that implement functionality in software enable flexibility and capability for application to embedded devices designed either to include or exclude DVS hardware. Typically, all functionality and features for a software-based implementation are common on embedded devices. The model can be adapted to changes in critical path due to variation in process and/or subsequently discovered phenomenon that changes electronic circuit performance.

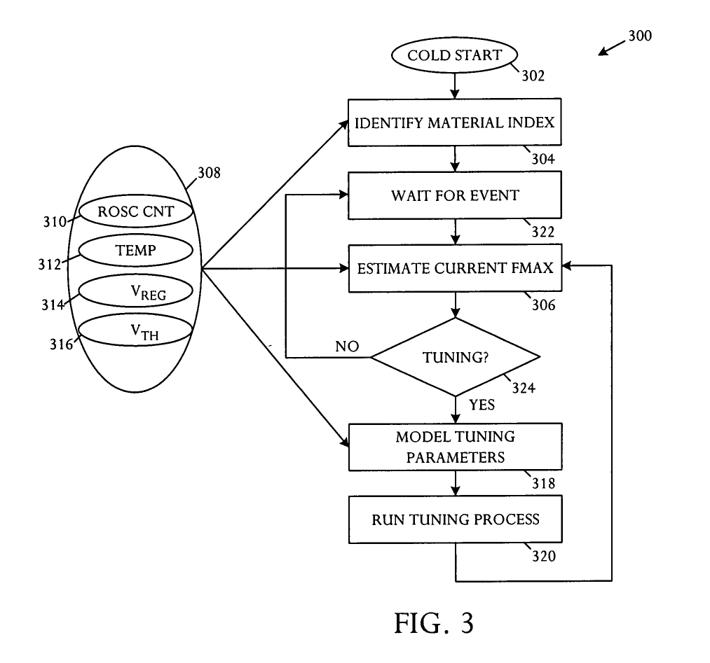

Referring to FIG. 3, a flow chart shows an embodiment of a method 300 for operating an electronic circuit. The illustrative technique begins by applying 302 a core voltage to the electronic circuit from a cold start. A material index is identified 304 based on known physical device characteristics for the electronic circuit, as well as a measured operating frequency at which the electronic circuit operates. A maximum frequency is estimated 306 for a critical path in the electronic circuit based on the material index and operating frequency. Typical physical device characteristics include material, temperature, and voltage characteristics.

The method can further include dynamically acquiring measurements 308 of critical path parameters selected from among ring oscillator count 310, temperature 312, regulated voltage V_{REG} 314, and threshold voltage V_{TH} 316. The critical path is modeled 318 using the measured dynamic parameters. The electronic circuit can be tuned 320 based on the model.

The method can be implemented to respond to real-time changes in conditions, for example by waiting 322 for a predefined event and triggering the estimation of maximum frequency 306 by the occurrence of the predefined event. Typical triggering events include interrupts, traps, detected changes in monitored conditions such as temperature or voltage changes, and the like. Once the current maximum frequency is estimated 306, a determination can be made 324 of whether to tune the electronic circuit. The determination is made based on the estimated maximum frequency.

The estimation of maximum frequency 306 can be made to correlate operating frequency behavior with critical path delay on the electronic circuit. The correlation can be extrapolated to determine a critical path delay in the current conditions. A minimum applied voltage can be generated and load capacitance margins set to meet the specified maximum frequency condition in the critical path. The load capacitance can be modeled separately from the modeling of voltage and temperature. For example, the load capacitance can be modeled based on a clock tree on the critical path.

In a particular embodiment, the model can be implemented in a system that incorporates Dual-Mode Subscriber Software (DMSS™), a trademark of Qualcomm, Inc. of San Diego, Calif. Yield improvements results from material dependent processing in DMSS. For example, a fast material generally has a relatively high quiescent supply current (IDDQ), the current that flows in static Complementary Metal-Oxide Semiconductor (CMOS) logic when the clock is stopped. Theoretically, IDDQ should be close to zero current. Because maximum frequency F_{MAX} is higher in integrated circuit segments with fast character, DMSS can manage the integrated circuit operating parameters to operate at a lower core voltage when the circuit is in a sleep state. In contrast, slow material devices may have a large proportion of devices that are unusable due to the F_{MAX} margins. The DMSS can be configured to operate at slower speeds with slower parts, thus increasing the yield from corners of the wafer that typically produce the slowest devices.

A dynamic voltage scaling (DVS) reference model implemented in software is more adaptable to changes in critical path due to process variation or other significant phenomena that may be overlooked during product design. Examples of such phenomena include droop in regulated voltage V_{REG} which can alter the device critical path. For example, V_{REG} droop may move the critical path from cache to static dynamic random-access memory (SDRAM) in some configurations.

The software implementation further increases system robustness since the model can be generated after full characterization of the integrated circuit and product. The software model also enables highly flexible implementation since the model can be used with a Power Management Integrated Circuit (PMIC) or other power management hardware. In an illustrative embodiment, the model can be implemented in a Mobile Station Modem (MSM)™ integrated circuit and system software made available by Qualcomm, Inc. of San Diego, Calif., or other suitable processor or chipset. The disclosed system may also be used in implementations in future chipsets that are designed with single rails or multiple rails with copies of the proposed model used for optimizing voltage on individual rails, depending on respective critical paths associated with the rails.

The illustrative system can reduce system power consumption and requirements since the model operates on a running core at optimal voltage settings.

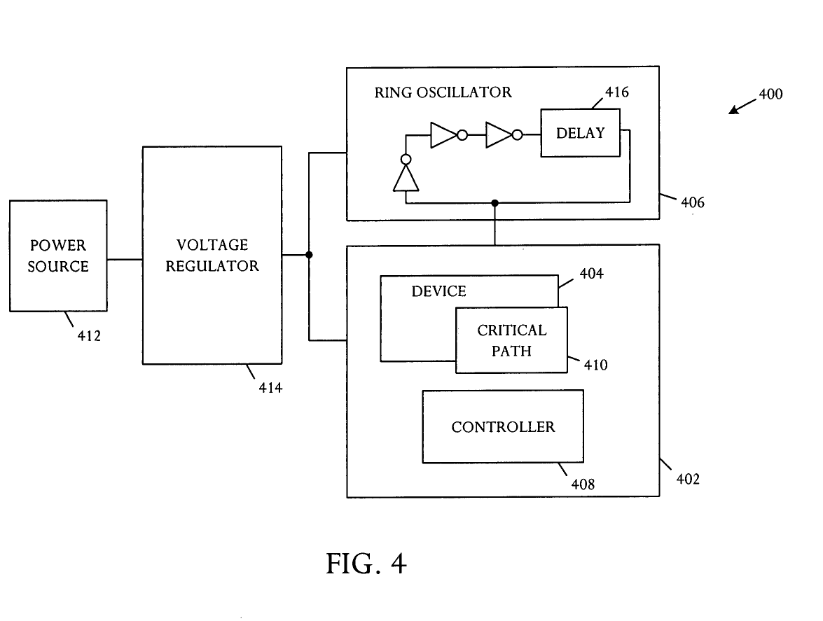

Referring to FIG. 4, a schematic block diagram illustrates an embodiment of an integrated circuit 400 including a core 402 with at least one electronic component and/or device 404. The core 402 has known material, temperature, and voltage characteristics. The integrated circuit 400 further includes an oscillator 406 coupled to the core 402 that generates a timing signal for usage by the core 402. A controller 408 is coupled to the core 402 and the oscillator 406. The controller 408 monitors one or more operational parameters of the core 402 at application of a core voltage to the electronic component and/or device from a cold start. The controller 408 uses the monitored parameter or parameters and estimates a maximum frequency for a critical path in the electronic component and/or device 404 based on a material index derived from the known physical device characteristics such as material, temperature, and voltage characteristics, and a measured electronic circuit operating frequency.

A critical delay pathway 410 exists in the core 402. The critical delay pathway 410 can have various positioning depending on particular operating conditions and circumstances. The controller 408 tunes the electronic component and/or device 404 based on a model of the critical path according to measured critical path parameters selected from among voltage, temperature, and/or load capacitance. The controller 408 determines the material index, for example based on an equation (1). In an illustrative embodiment, the controller 408 waits for a predefined event to trigger maximum frequency estimation, and determines whether to tune the electronic component and/or device 404 based on the estimated maximum frequency. The controller 408 correlates operating frequency behavior with critical path delay on the electronic component and/or device 404, and extrapolates the correlation to determine a critical path delay in selected conditions. The controller 408 generates a minimum applied voltage and load capacitance with margins set to meet a specified maximum frequency in the critical path.

The controller 408 controls power applied to the core 402 by adjusting selected operational parameters. A selected voltage may be generated by connecting a power source 412 to a voltage regulator 414 and supplying the regulated voltage to power the core 402. A selected clock frequency can be controlled by using a delay element 416 to control a variable-frequency clock, such as the oscillator 406. In one example, the oscillator 406 may be a voltage-controlled oscillator. The oscillator 406 generates a clock signal with a frequency that is based on propagation delay in a pathway in the core 402. Various factors, for example temperature, materials, and variability in fabrication process may result in differences in propagation delay in the integrated circuit 400. The voltage regulator 414 can be controlled to vary the voltage applied to the core 402 and the oscillator 406 may be controlled to vary frequency. For example, the controller 408 may reduce the applied core voltage and simultaneously reduce the operating frequency to compensate for the lower voltage. Coordinated management of the applied core voltage and operating frequency can be used to reduce power consumption while ensuring an appropriate operating speed to attain processing functionality.

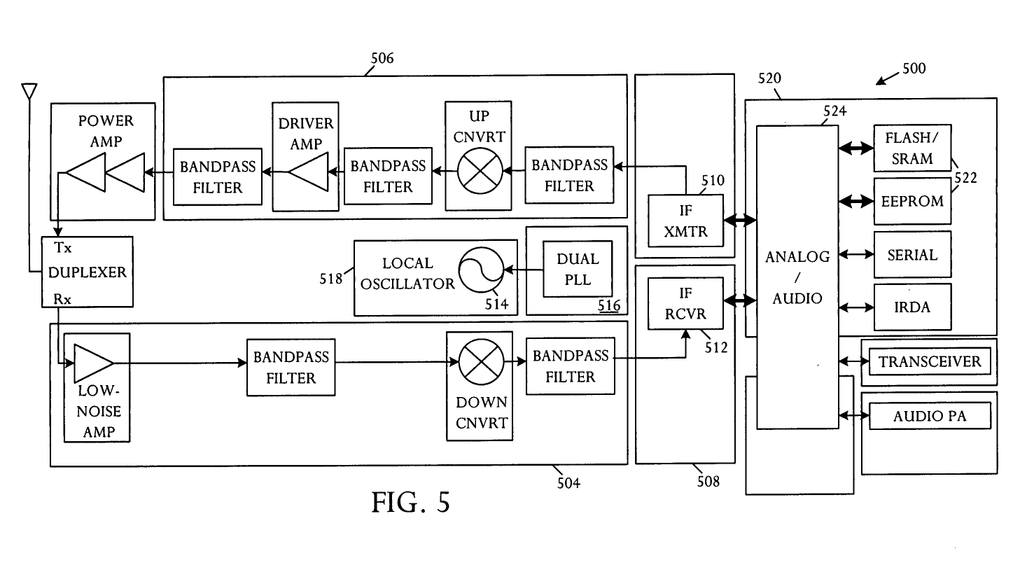

Referring to FIG. 5, a schematic block diagram illustrates an embodiment of a cellular telephone 500 that can implement the illustrative technique for operating a device at an optimal core voltage. In an illustrative implementation the cellular phone 500 can be a Code Division Multiple Access (CDMA) wireless telephone. The cellular phone 500 includes a radio frequency (RF) receiver block 504 and an RF transmitter block 506, and a baseband block 508. The baseband block 508 further includes an Intermediate Frequency (IF) transmitter 510 and IF receiver 512, a Voltage-Controlled Oscillator (VCO) 514, a Phase-Locked Loop (PLL)/synthesizer block 516, a Temperature-Compensated Crystal Oscillator (TCXO) block 518, and a Mobile Station Modem (MSM)™ processor 520 and associated subsystem including memories 522 and audio 524, and keypad. The RF transmitter 506 generates an RF wave signal and the RF receiver 504 converts a received RF wave to an analog signal. The baseband block 508 and the processor 520 process the digital and analog signals, and convert the received signal to sound through a coding/decoding (codec) functionality. Low drop-out linear regulators (LDOS) supply power management functionality. Typically, a suitable number of LDOs are distributed throughout various blocks in the cellular phone 500.

An illustrative RF receiver block 504 includes a low noise amplifier, surface-acoustic wave (SAW) filters, a mixer, and an automatic gain control (AGC) amplifier. An illustrative RF transmitter block 506 includes an isolator, a power amplifier (PAM), SAW filters, an AGC amplifier, and a mixer.

While the present disclosure describes various embodiments, these embodiments are to be understood as illustrative and do not limit the claim scope. Many variations, modifications, additions and improvements of the described embodiments are possible. For example, those having ordinary skill in the art will readily implement the steps necessary to provide the structures and methods disclosed herein, and will understand that the process parameters, materials, and dimensions are given by way of example only. The parameters, materials, components, and dimensions can be varied to achieve the desired structure as well as modifications, which are within the scope of the claims. For example, the illustrative methods and structures can be used in any suitable semiconductor technology and is not limited those particularly named. Furthermore, the structures and methods can be used in any appropriate amplifiers, receivers, and communication devices other than those described and named. In addition, the disclosed structures and methods can be used in any suitable applications, extending beyond the particular applications described.

What is claimed is:

1. A method for operating an electronic circuit including an oscillator and having known physical device characteristics, the method comprising:
supplying a core voltage to the electronic circuit from a cold start;
measuring output frequency of the oscillator during the cold start; and
determining a material index from the output frequency based on the physical device characteristics.

2. The method according to claim 1 wherein the physical device characteristics include material, temperature, and voltage characteristics.

3. The method according to claim 1 further comprising:
estimating a maximum frequency for a critical path in the electronic circuit based on the material index and frequency of the oscillator.

4. The method according to claim 1 further comprising:
determining the material index based on an equation of the form:
Fₒᵤₜ=mx·X+δT·(T_{REF}−T_{INST})+δV·(V_{INST}−V_{REF})
whereby Fₒᵤₜ is the output frequency of the oscillator, mx is a material constant, X is the material index, δT is a temperature gradient, T_{REF} is a reference temperature, T_{INST} is instantaneous temperature, δV is a voltage gradient, V_{INST} is an instantaneous voltage, and V_{REF} is a reference voltage.

5. The method according to claim 1 further comprising:
approximating a maximum frequency for a critical path in the electronic circuit based on the material index and frequency of the oscillator; and
for an application whereby delay in the critical path is unsuitable, adjusting the core voltage and/or a clock tree capacitance to change the critical path delay to a suitable range.

6. The method according to claim 1 further comprising:
correlating oscillator behavior with critical path delay of the electronic circuit; and
generating a minimum core voltage and adjusting load capacitance within selected margins to produce a controlled maximum frequency in the critical path.

7. The method according to claim 1 further comprising:
implementing the method as a reference model in software; and
adapting the model to changes in critical path due to variation in process and/or subsequently discovered phenomenon that changes electronic circuit performance.

8. An integrated circuit comprising:
a core including at least one electronic component and/or device and having known physical device characteristics;
an oscillator coupled to the core that generates a timing signal for usage by the core; and
a controller coupled to the core and the oscillator that measures oscillator output frequency during a cold start and determines a material index from the output frequency based on the physical device characteristics.

9. The integrated circuit according to claim 8 wherein the physical device characteristics include material, temperature, and voltage characteristics.

10. The integrated circuit according to claim 8 further comprising:
a critical delay pathway in the core, the controller estimating a maximum frequency for the critical path based on the material index and frequency of the oscillator.

11. The integrated circuit according to claim 8 wherein:
the controller determines the material index based on an equation of the form:
Fₒᵤₜ=mx·X+δT·(T_{REF}−T_{INST})+δV·(V_{INST}−V_{REF})
whereby Fₒᵤₜ is the output frequency of the oscillator, mx is a material constant, X is the material index, δT is a temperature gradient, T_{REF} is a reference temperature, T_{INST} is instantaneous temperature, δV is a voltage gradient, V_{INST} is an instantaneous voltage, and V_{REF} is a reference voltage.

12. The integrated circuit according to claim 8 wherein:
the controller approximates a maximum frequency for the critical path based on the material index and frequency of the oscillator, and for an application whereby delay in the critical path is unsuitable, adjusts the core voltage and/or a clock tree capacitance to change the critical path delay to a suitable range.

13. The integrated circuit according to claim 8 wherein:
the controller correlates oscillator behavior with critical path delay of the electronic circuit, and generates a minimum core voltage and adjusts load capacitance within selected margins to produce a controlled maximum frequency in the critical path.

14. The integrated circuit according to claim 8 further comprising:
a controller usable medium having a computable readable program code embodied therein including a program code that implements a reference model in software and adapts the model to changes in critical path due to variation in process and/or subsequently discovered phenomenon that changes core performance.

15. A method for operating an electronic circuit comprising:
applying a core voltage to the electronic circuit from a cold start;
identifying a material index based on known physical device characteristics for the electronic circuit and a measured operating frequency at which the electronic circuit operates;
estimating a maximum frequency for a critical path in the electronic circuit based on the material index and operating frequency.

16. The method according to claim 15 wherein the physical device characteristics include material, temperature, and voltage characteristics.

17. The method according to claim 15 further comprising:
dynamically measuring critical path parameters selected from among voltage, temperature, and/or load capacitance;
modeling the critical path according to measured dynamic parameters; and
tuning the electronic circuit based on the model.

18. The method according to claim 17 further comprising:
waiting for a predefined event;
triggering maximum frequency estimation by occurrence of the predefined event; and
determining whether to tune the electronic circuit based on the estimated maximum frequency.

19. The method according to claim 17 further comprising:
correlating operating frequency behavior with critical path delay on the electronic circuit.

20. The method according to claim 19 further comprising:
extrapolating the correlation to determine a critical path delay in current conditions.

21. The method according to claim 20 further comprising:
generating a minimum applied voltage and load capacitance with margins set to meet a specified maximum frequency in the critical path.

22. The method according to claim 15 further comprising:
determining the material index based on an equation of the form:
Fₒᵤₜ=mx·X+δT·(T_{REF}−T_{INST})+δV·(V_{INST}−V_{REF})
whereby Fₒᵤₜ is the operating frequency, mx is a material constant, X is the material index, δT is a temperature gradient, T_{REF} is a reference temperature, T_{INST} is instantaneous temperature, δV is a voltage gradient, V_{INST} is an instantaneous voltage, and V_{REF} is a reference voltage.

23. The method according to claim 15 further comprising:
modeling load capacitance separately from modeling of voltage and temperature, the load capacitance being modeled based on a clock tree on the critical path.

24. An integrated circuit comprising:
a core including at least one electronic component and/or device and having known physical device characteristics;
an oscillator coupled to the core that generates a timing signal for usage by the core; and
a controller coupled to the core and the oscillator that monitors at least one operational parameter of the core at application of a core voltage to the electronic component and/or device from a cold start and estimates a maximum frequency for a critical path in the electronic component and/or device based on a material index derived from the known physical device characteristics, and a measured electronic circuit operating frequency.

25. The integrated circuit according to claim 24 wherein the physical device characteristics include material, temperature, and voltage characteristics.

26. The integrated circuit according to claim 24 further comprising:
a critical delay pathway in the core, the controller tuning the electronic component and/or device based on a model of the critical path according to measured critical path parameters selected from among voltage, temperature, and/or load capacitance.

27. The integrated circuit according to claim 24 wherein:
the controller determines the material index based on an equation of the form:
Fₒᵤₜ=mx·X+δT·(T_{REF}−T_{INST})+δV·(V_{INST}−V_{REF})
whereby Fₒᵤₜ is the output frequency of the oscillator, mx is a material constant, X is the material index, δT is a temperature gradient, T_{REF} is a reference temperature, T_{INST} is instantaneous temperature, δV is a voltage gradient, V_{INST} is an instantaneous voltage, and V_{REF} is a reference voltage.

28. The integrated circuit according to claim 24 wherein:
the controller waits for a predefined event to trigger maximum frequency estimation, and determines whether to tune the electronic component and/or device based on the estimated maximum frequency.

29. The integrated circuit according to claim 24 wherein:
the controller correlates operating frequency behavior with critical path delay on the electronic component and/or device, extrapolates the correlation to determine a critical path delay in selected conditions, and generates a minimum applied voltage and load capacitance with margins set to meet a specified maximum frequency in the critical path.

30. A cellular telephone including the integrated circuit according to claim 24.
